(19) United States
(12) Patent Application Publication
(10) Pub. No.: US 2002/0138804 A1
(43) Pub. Date: Sep. 26, 2002

(54) Computation of checksums and other functions with the aid of software instructions

(76) Inventors: Onkar S. Sangha, San Jose, CA (US); Vijay Maheshwari, Fremont, CA (US); Jiinyuan Lee, San Jose, CA (US)

Correspondence Address: Michael Shenker, SKJERVEN MORRILL MacPHERSON LLP, Suite 700, 25 Metro Drive, San Jose, CA, 95110-1349, US

(21) Appl. No.: 09/771,020

(22) Filed: Jan. 25, 2001

(51) Int. Cl. H03M 13/00; G06F 11/10; G11C 29/00

(52) U.S. Cl. 714/758; 714/807

(57) ABSTRACT

In order to speed up software computation of CRC, scrambler, descrambler, or other functions used to enhance reliability of data transmission, a software instruction is provided which performs a partial or complete computation of the function. A register may be provided to store a value identifying the function to be computed if multiple functions can be computed in a particular embodiment. A register can also be provided to store the number of bits on which a computation invoked by the software instruction is to be performed. Bit ordering (for example, big endian or little endian) can also be specified by a value or values stored in a register.

### BACKGROUND OF THE INVENTION

The present invention relates to computation of functions that can be used to increase reliability of data transmission. One example of such a function is cyclic redundancy check sum (CRC). Other examples include data scramblers and descramblers.

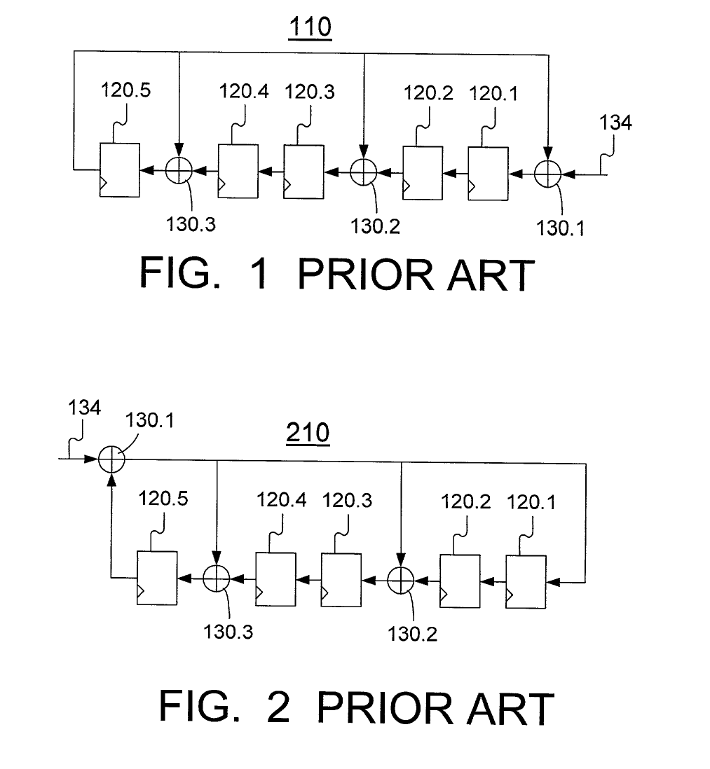

FIG. 1 shows a conventional circuit 110 that computes a cyclic redundancy check sum CRC5 defined by a generator polynomial G(x)=x⁵+x⁴+x²+1. Circuit 110 includes a shift register having five latches 120.1, 120.2, 120.3, 120.4, 120.5. (If a generator polynomial has a degree “r”, then r latches are provided). XOR gates (modulo 2 adders) 130.1, 130.2, 130.3 are inserted into the shift register at locations corresponding to non-zero terms of the generator polynomial, except that no XOR gate is provided for the highest degree term x⁵. The term x⁴ corresponds to gate 130.3 inserted before the latch 120.5. The term x² corresponds to gate 130.2 before the latch 120.3. The term 1 corresponds to gate 130.1 before latch 120.1. (Generally, for each term xⁱ⁺¹ other than x^{r}, an XOR gate is provided before the ith latch 120.i.) The output of the last latch 120.5 is fed to all of the XOR gates. Each XOR gate except the gate 130.1 also receives the output of the corresponding preceding latch 120. XOR gate 130.1 receives the input data (the bits of a message on which the CRC is to be computed) from lead 134. (If a generator polynomial does not have a 1 term (x⁰ term), then the input data are provided directly to the latch 120.1.)

The input message is provided serially on lead 134, one bit per clock cycle. When the whole message has been fed in followed by five zeroes (five being the degree of the generator polynomial), the latches 120 contain the CRC value. The CRC value is the remainder of a division operation in which a polynomial whose coefficients are the bits of the input message is divided by the generator polynomial. See, for example, Encyclopedia of Computer Science and Engineering (Van Nostrand Reinhold Company, 1983), pages 435-437, incorporated herein by reference.

FIG. 2 shows another conventional circuit 210 for computing the CRC5 check sum for the same generator polynomial as circuit 110. Circuit 210 is similar to circuit 110 except that in circuit 210 each of XOR gates 130.2, 130.3 receives the signal at the input of latch 120.1 instead of the output of latch 120.5. When the whole message has been fed into the circuit 210 via lead 134, the latches 120 contain the CRC value. (The message is not followed by zeroes in this case.) Hardware implementations of the CRC computations, such as the implementations of FIGS. 1 and 2, are fast but inflexible. In some applications, it is desirable to provide a user with flexibility in deciding at what points in the data processing the CRC values are computed. This kind of flexibility can be provided by implementing CRC computations in software. However, software computations using typical instructions such as XOR, shift, and other logical and arithmetic instructions, are slow. Software computations are especially slow if the generator polynomial has many terms since each term except the highest degree term corresponds to an XOR operation.

Improved techniques for computing CRC values and other functions, such as scrambler and descrambler functions, are desirable.

### SUMMARY

Some embodiments of the present invention speed up software-implemented CRC computations by performing at least a partial CRC computation in response to a single software instruction. In some embodiments, the generator polynomial defining a CRC has at least three terms. (Therefore, a circuit of the type of FIG. 1 or 2 would have at least two XOR gates.)

Some embodiments facilitate computation of other check functions, not necessarily CRC, and also of scrambler functions providing scrambled data, and descrambler functions providing descrambled data. An instruction execution circuit executing the pertinent software instruction can perform computations for multiple functions. A register is provided to specify the function to be computed. When the software instruction is received, the instruction execution circuit reads the register and performs a computation for the function identified by the register.

In some embodiments, an instruction execution circuit internally stores results of computations for different functions. A software instruction is provided to read a result. A register specifies the function whose result is to be provided in response to the software instruction.

In other embodiments, an instruction execution circuit performs computations for only one function.

In some embodiments, a register is provided to specify a number of bits on which a computation is to be performed. In some embodiments, a register is provided to specify an ordering (for example, big endian or little endian) for a computation.

In some embodiments, the instruction execution circuit is a coprocessor of a standard processor, for example, a MIPS processor. The processor communicates with the coprocessor via a standard instruction set, such as the read and write instructions for reading and writing the coprocessor registers. An instruction to write a coprocessor register is interpreted by a coprocessor as an instruction to perform a CRC computation or a computation for some other check function or a scrambler or descramnbler function. An instruction to read a coprocessor register is interpreted as an instruction to read the result of a computation.

The invention is not limited to the embodiments described above. Other features and advantages of the invention are described below. The invention is defined by the appended claims.

### DESCRIPTION OF PREFERRED EMBODIMENTS

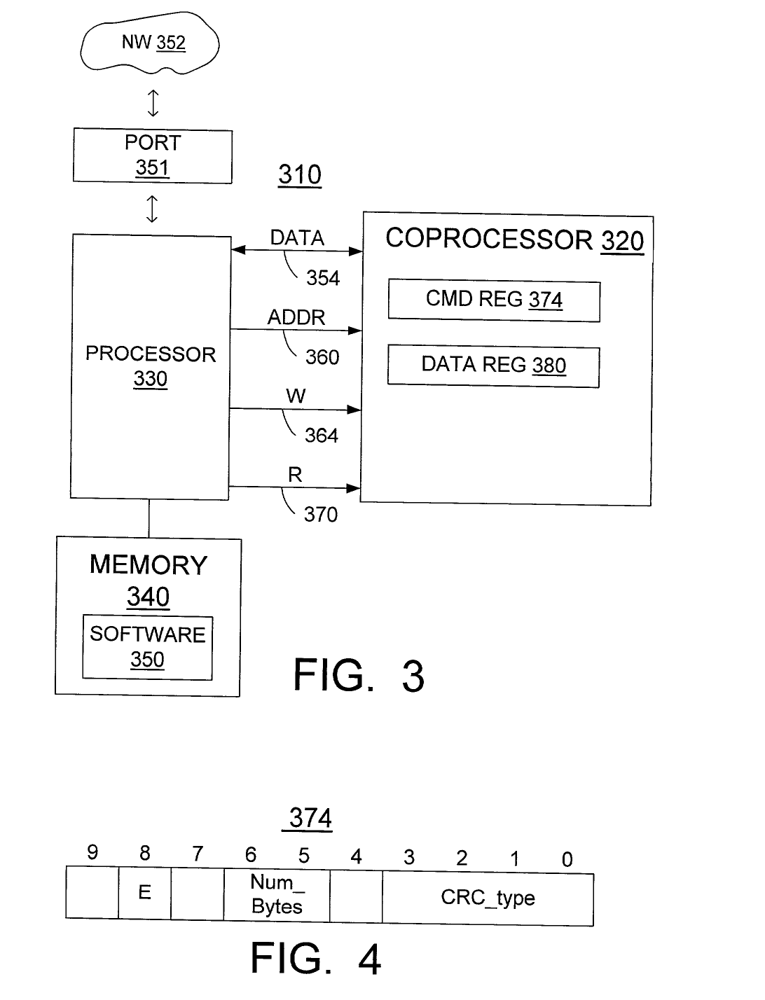

FIG. 3 illustrates a software programmable computer system 310 that can perform a complex CRC computation in response to a single software instruction. The CRC computations are performed by a coprocessor 320 controlled by a software programmable computer processor 330. In some embodiments, processor 330 is a conventional processor having a conventional instruction set. For example, a MIPS I® microprocessor of type LX4180 available from Lexra, Inc. of San Jose, Calif. can be used. The CRC computations are performed by coprocessor 320 in response to a conventional software instruction such as write to a coprocessor register. This architecture allows one to use an off-the-shelf processor 330 and avoid modification of the instruction set. The invention is not limited to such embodiments, however. In some embodiments, specialized software instructions are provided to perform CRC computations. The CRC computations can be performed by circuitry integrated into the processor 330 without using a coprocessor interface.

FIG. 3 also shows a memory 340 which stores software 350 executed by the processor 330. The software can be prepared before the processor 330 begins operation. Memory 340 can be a non-volatile memory, or it can be a volatile memory into which the software is loaded from some non-volatile storage using known techniques.

FIG. 3 also shows a network port 351 through which the system 310 is connected to a network 352. Network data units received on port 351 are accompanied by CRC values. For each data unit, the corresponding CRC was computed when the data unit was transmitted to system 310. Processor 330 uses coprocessor 320 to recompute the CRC on the data unit. Processor 330, or some other circuit, then compares the recomputed CRC with the CRC received with the data unit to determine if the data unit has been received correctly.

When system 310 transmits data network 352, processor 330 uses coprocessor 320 to compute a CRC on the data. The CRC is transmitted with the data.

In some embodiments, processor 330 can use coprocessor 320 to scramble data before transmission and descramble received data. Data scrambling is used to remove long strings of 1's and 0's and to make the 1's and 0's appear more random. See W. Stallings, “ISDN and Broadband ISDN with Frame Relay and ATM” (4th ed, 1999), pages 58-59, incorporated herein by reference.

We will now describe a detailed implementation of one embodiment of FIG. 3. The details given below are provided for illustration and are not limiting.

The interface between processor 330 and coprocessor 320 includes the following lines:

1. Data bus 354. When processor 330 executes an instruction to write to a coprocessor register, processor 330 drives write data on data bus 354. When the processor executes an instruction to read a coprocessor register (in order to read the result of a CRC computation, for example), coprocessor 320 drives read data on the data bus. For the purpose of illustration, we will assume that the data bus is 32 bits wide.

2. Address bus 360. When processor 330 executes an instruction to write or read a coprocessor register, processor 330 drives address bus 360 with address signals identifying the register. In some embodiments, only four address values are needed, so address bus 360 contains only two lines. In other embodiments, coprocessor 320 may perform other functions not related to CRC computations or scrambling. Address bus 360 may contain additional lines to enable one to access registers not related to CRC computations or scrambling.

3. Write line 364 is asserted by processor 330 when the processor executes an instruction to write a coprocessor register.

4. Read line 370 is asserted by processor 330 when the processor executes an instruction to read a coprocessor register.

Coprocessor 320 includes a command register 374 and a data register 380. Data register 380 contains data on which the CRC is to be computed or scrambling or descrambling is to be performed. This is a 32-bit register. The CRC, scrambling and descrambling computations are initiated when the data register is written.

FIG. 4 illustrates the command register 374. Ten bits [9:0] are illustrated, which are mapped to ten lines DATA[9:0] of data bus 354. Lines DATA[9:0] carry the respective bit values of command register 374 when the command register is read or written.

Bits [3:0] (“CRC_type”) of register 374 specify the CRC involved in the operation performed by the processor. Table 1 below shows CRC_type values for one embodiment. As shown in Table 1, coprocessor 320 can calculate a CRC5, two CRC8's with different generator polynomials, and other CRC types. Coprocessor 320 can also perform scrambling, descrambling, and byte swapping. When processor 330 writes the data register 380, bits [3:0] of the command register specify which of the operations in Table 1 must be performed on the data being written to the data register. When processor 330 executes a read-coprocessor-register instruction to read a result of an operation, bits [3:0] of the command register specify the operation whose result is being read.

Bit [4] of the command register does not exist. This bit is mapped to line DATA[4] of data bus 354. During execution of an instruction to write the command register, the line DATA[4] specifies if bits [3:0] of the command register must be written. If DATA[4] is asserted, the command register bits [3:0] are written. If line DATA[4] is deasserted, the command register bits [3:0] are not written.

Bits [6:5] of the command register (“Num_Bytes”) specify the number of bytes (and hence the number of bits) on which an operation is to be performed when processor 330 executes an instruction to write the data register 380. Some embodiments allow one to specify 1, 2, 3, or 4 bytes (8, 16, 24, or 32 bits).

Bit [7] of the command register does not exist. This bit is mapped to line DATA[7] of data bus 354. During execution of an instruction to write the command register, bits [6:5] of the command register are written if, and only if, line DATA[7] is asserted.

Bit [8] (the “E” bit) specifies the endianness (big endian or little endian) for the CRC, scrambling and descrambling operations. If the operation is big endian, the operation is first performed on bits [24:31] of data register 380, then on bits [16:23], then on bits [8:15], then on bits [0:7]. (If the Num_Bytes field of the command register specifies less than 4 bytes, then the operation is performed on less than four bytes, starting with the bits [24:31] of the data register). If the E bit of the command register specifies a little endian operation, the CRC computation is performed first on bits [0:7] of the data register, then on bits [8:15], then on bits [16:23], then on bits [24:31] (up to the number of bytes specified by the Num_Bytes field).

Bit [9] of the command register does not exist. This bit is mapped to line DATA[9] of data bus 354. When the command register is written, line DATA[9] specifies whether the E bit of the command register will be written, similarly to lines DATA [7] and DATA [4].

To read a result of an operation, the processor 330 executes an instruction to read a register “state 0” or “state 1”. These registers do not exist, but each of these registers is assigned a register address. When the address is driven on address bus 360, coprocessor 320 drives the data bus 354 with the result of an operation specified by the CRC_type field of the command register. Register “state 0” is used to read up to 32 bits of the result. Register “state 1” is used to read the remaining bits.

Processor 330 writes the “state 0” and “state 1” registers to provide the starting value for a CRC computation or a scrambling or descrambling operation. The starting value may be an initial value (e.g., 0) or an intermediate value.

TABLE 1

| | Operation performed when data register 380 is written or |
|---|---|
| CRC_type | when “state 0” or “state 1” register is read |
| 0000 | CRC5. Generator polynomial is x⁵ + x² + 1 |
| 0001 | CRC6. Generator polynomial is x⁶ + x² + 1 |
| 0010 | CRC8. Generator polynomial is x⁸ + x² + x + 1 |
| 0011 | CRC10. Generator polynomial is x¹⁰ + x⁹ + x⁵ + x⁴ + x + 1 |
| 0100 | CRC16. Generator polynomial is x¹⁶ + x¹² + x⁵ + 1 |
| 0101 | CRC32. Generator polynomial is |
| | x³² + x²⁶ + x²³ + x²² + x¹⁶ + x¹² + |
| | x¹¹ + x¹⁰ + x⁸ + x⁷ + x⁵ + x⁴ + x² + |
| | x + 1 |
| 0110 | Scrambler. Generator polynomial is x⁴³ + 1 |
| 0111 | Byte swapping. When the state 0 register is read, the bits |
| | DR[31:0] of data register 380 are written to lines |
| | DATA[31:0] of data bus 354 as follows: |
| | DR[31:24]−>DATA[7:0] |
| | DR[23:16]−>DATA[15:8] |
| | DR[15:8]−>DATA[23:16] |
| | DR[7:0]−>DATA[31:24] |
| 1000 | Lower half word swapping. When the state 0 register is |
| | read, the bits DR[31:0] of data register 380 are |
| | written to lines DATA[31:0] of data bus 354 as follows: |
| | DR[31:24]−>DATA[31:24] |
| | DR[23:16]−>DATA[23:16] |
| | DR[15:8]−>DATA[7:0] |
| | DR[7:0]−>DATA[15:0] |
| 1001 | Swapping of both half words. When the state 0 register is |
| | read, the bits DR[31:0] of data register 380 are |
| | written to lines DATA[31:0] of data bus 354 as follows: |
| | DR[31:24]−>DATA[23:16] |
| | DR[23:16]−>DATA[31:24] |
| | DR[15:8]−>DATA[7:0] |
| | DR[7:0]−>DATA[15:0] |
| 1010 | CRC8. Generator polynomial is x⁸ + x⁴ + x³ + x² + 1 |
| 1011 | CRC15. Generator polynomial is x¹⁵ + x¹⁴ + 1 |
| 1100 | Descrambler. When the state 0 register is read by |
| | processor 330, the descrambler result is written to the data |
| | bus by coprocessor 320. If the descrambler read operation is |
| | 3, 2, or 1 bytes as specified by Num_Bytes in the |
| | command register, then the least significant 3, 2, or 1 bytes |
| | are written to the data bus. (The least significant bit is the |
| | last bit descrambled.) |
| | If the state 0 register is written by processor 330, then the |
| | descrambler state 0 portion is written. |
| 1101 | Descrambler. Read or write access to the state 0 and state 1 |
| | registers by processor 330 results in the read or write access |
| | to the state 0 and state 1 portions of the descrambler state. |

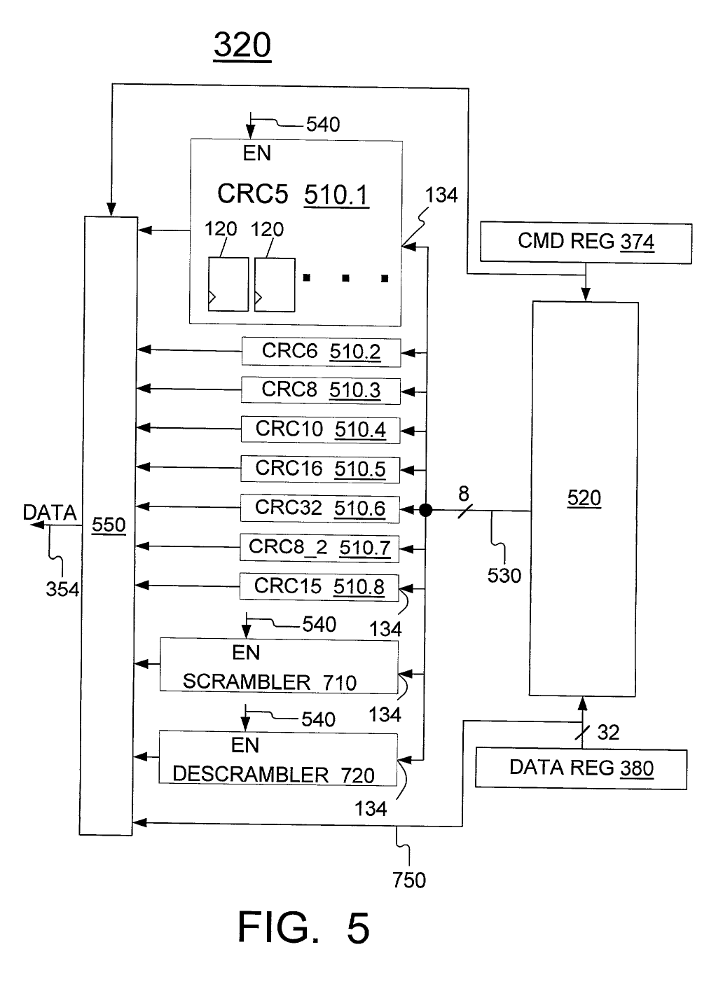

FIG. 5 illustrates coprocessor 320 in detail. Each CRC operation in Table 1 is executed by a corresponding circuit 510. Each of these circuits 510.1 . . . 510.8 can be similar to any of the circuits of FIGS. 1 and 2. In particular, each circuit 510 contains latches 120 to store the respective bits of the CRC remainder. (In FIG. 5, the latches are shown only for circuit 510.1.) The latches can be connected to form a shift register, as in FIGS. 1 and 2. Alternatively, a circuit 510 can contain combinational circuitry that performs a CRC computation on eight bits (or some other number of bits) of input data in a single clock cycle and loads the result of the computation into the corresponding latches 120. In FIG. 5, each circuit 510 receives eight bits of input data on the respective 8-bit input 134.

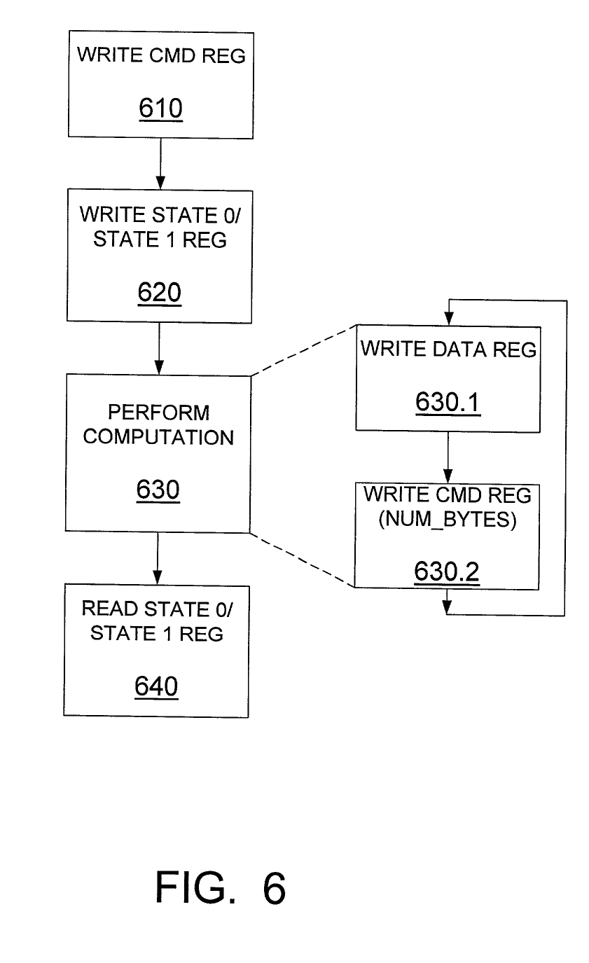

Other features of coprocessor 320 will be explained with reference to FIG. 6. FIG. 6 illustrates a software program that can be executed by processor 330 to perform a complete or partial CRC computation on a data message. At stage 610, processor 330 executes an instruction to write the command register 374. The command register fields CRC_type (bits [3:0]), Num_Bytes (bits [6:5]), and E (bit [8]) are written at this stage.

At stage 620, the processor executes an instruction to write the “state 0” register with a starting value for the CRC computation. The processors drives the starting value on data bus 354. Coprocessor 320 reads the CRCtype value from the command register, and loads the starting value into latches 120 of the circuit 510 corresponding to the CRC_type value. If the circuit 510 has not yet started the CRC computation on a message, the initial value may be zero. If the computation has started but has not been performed on the entire message, the intermediate value is loaded. The ability to load an intermediate value is desirable in applications such as described, for example, in U.S. Pat. No. 5,642,347, issued on Jun. 24, 1997 and incorporated herein by references. That patent describes CRC computation for data packets received by a device from an ATM (asynchronous transfer mode) network. The packets are received in the AAL5 (ATM Adaptation Layer 5) format. Each packet carries a CRC32 check sum. ATM cells of different packets may arrive at the device intermixed. The device performs the CRC32 computation for each cell in the order in which the cells are received. After the device has performed a CRC computation on one or more cells of one packet (“first” packet), the device may have to interrupt the computation and start a CRC computation on another packet. The intermediate result of the interrupted computation is unloaded from the CRC computation circuit and temporarily stored in a memory. When another cell is received for the first packet, the intermediate result is reloaded into the CRC circuit, and the CRC computation for the first packet is restarted.

At stage 630, processor 330 performs the CRC computation to compute the final CRC value or an intermediate value based on less than the entire message. At sub-stage 630.1, processor 330 executes an instruction to write data register 380 with up to 4 bytes of data on which the CRC computation is to be performed. Starting with the clock cycle in which the data are driven on bus 354, circuit 520 (FIG. 5) provides individual data octets from data register 380 on 8-bit bus 530. One octet is provided in each clock cycle. The octets are provided in the order defined by the E bit of the command register (FIG. 4). The number of octets to be provided on bus 530 is defined by the Num_Bytes field of the command register. This field also defines the number of clock cycles needed to execute the instruction.

Bus 520 is connected to 8-bit data inputs 134 of circuits 510. Each circuit 510 has an enable input 540 (shown for circuit 510.1) for receiving a corresponding enable signal. Coprocessor 320 reads the CRC_type field of the command register and asserts the enable input 540 of the corresponding circuit for the Num_Bytes clock cycles. In each clock cycle, the corresponding circuit 510 performs a CRC computation on the 8 bits provided on bus 530.

Sub-stage 630.1 may be repeated, i.e. processor 330 may execute multiple instructions to write the data register. Between different instances of stage 630.1, (i.e. between instructions to write the data register) sub-stage 630.2 may be inserted to write the command register with new Num_Bytes or E values.

At stage 640, processor 330 executes an instruction to read the state 0 register. Circuit 550 (FIG. 5) reads a value stored in the latches 120 of the circuit 510 identified by the CRC_type field of the command register. Circuit 550 drives this value on data bus 354. If this value is less than 32 bits wide, circuit 550 drives the unused lines of bus 354 with some predefined value, for example, zero. In some embodiments, the result of a CRC computation can have more than 32 bits. To read the remaining bits, processor 330 reads the state 1 register. In other embodiments, coprocessor 320 may provide more than 32 bits of data serially in response to a single instruction to read the state 0 register. In some embodiments, more than 32 bits of data can be read serially by repeated execution of the instruction to read the state 0 register.

Data scrambling is performed as follows. At stage 610, processor 330 writes the CRC_type field of the command register with the binary value 0110 (see Table 1). At stage 620, processor 330 writes the state 0 and state 1 registers to load a starting value into scrambler circuit 710 (FIG. 5). In one embodiment, scrambler 710 is similar to a CRC computation circuit with a generator polynomial x⁴³+1. Scrambler 710 has 43 latches 120 (not shown in FIG. 5) to hold the scrambled data. Thirty-two of these latches correspond to the state 0 register in register read and write operations. The remaining 11 latches correspond to the state 1 register.

At sub-stage 630.1, processor 330 writes data register 380 with data to be scrambled. Circuit 520 reads the CRC_type field of command register 374 and asserts an enable signal on input 540 of scrambler 710. Input circuit 520 reads the Num_Bytes field and the E field of the command register, and drives the data from data register 380 on bus 530, as in the CRC computations. The data are delivered to the scrambler's 8-bit input 134. Sub-stage 630.1 can be repeated as needed. Sub-stage 630.2 can be inserted to change the command register between different instances of sub-stage 630.1 as in the CRC computations.

At stage 640, processor 330 reads the state 0 and state 1 registers. In response, circuit 550 reads the CRC_type field of command register 374. This field specifies the scrambler. Circuit 550 drives the data bus 354 with the data stored in the scrambler's latches 120.

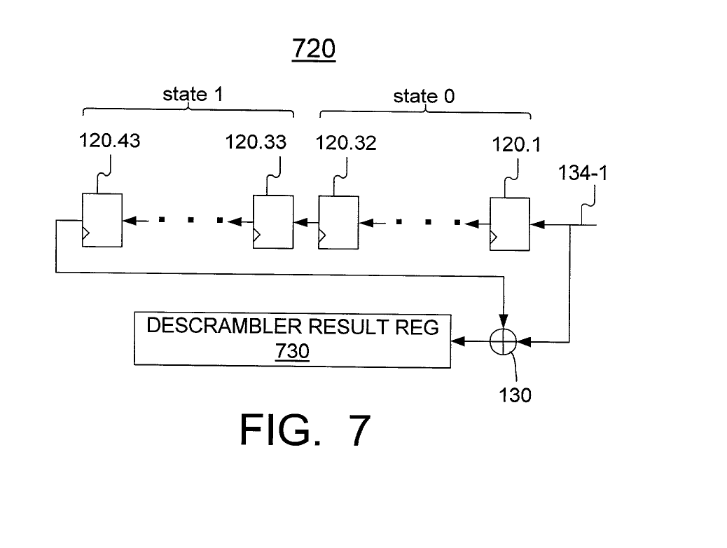

FIG. 7 is a conceptual diagram of descrambler 720. The descramnbler contains a 43-bit shift register formed by latches 120.1 through 120.43. Serial data are provided on one-bit input lead 134-1 directly to latch 120.1. The shift register output (the output of latch 120.43) is XORed with the input on lead 134-1 by XOR gate 130. The output of gate 130 provides descrambled data. The descrambled data are stored in shift register 730 (“descrambler result register”). Processor 330 can access this register by reading or writing the state 0 register when the CRC_type field of the command register is 1100.

In Table 1, the value in the descrambler's latches 120.1-120.43 is referred to as the descrambler state. Processor 330 can read and write the descrambler state by reading and writing the state 0 and state 1 registers when the CRC_type is 11 01. Latches 120.1-120.32 are accessed as the “state 0” register. Latches 120.33-120.43 are accessed as the “state 1” register. Latches 120.1-120.32 can also be written as the state 0 register when the CRC_type is 1100.

In the embodiment of FIG. 5, the descrambler 720 performs a descrambling operation on 8 bits of input data in a single clock cycle. The descrambler's input 134 is 8 bits wide.

A descrambling operation can be performed as in FIG. 6. At stage 610, processor 330 writes the command register. The CRC_type field is written with a binary value 1101 (see Table 1).

At stage 620, processor 330 executes instructions to write the state 0 and state 1 registers to load appropriate values into the descrambler state latches 120.1-120.43.

Then processor 330 writes the command register to change the CRC_type field to 1100. This stage is not shown in FIG. 6.

At stage 630.1, processor 330 writes the data register with data to be descrambled. Circuit 520 reads the CRC_type field of the command register and enables the descrambler 720 via the descrambler's input 540 (FIG. 5). Circuit 520 provides the data to be descrambled on bus 530 in accordance with the Num_Bytes and E fields of the command register, as in the CRC computations. The command register can be updated at stage 630.2 as described above for the CRC computations.

The number of bits descrambled at stage 630.1 should be such as not to overflow the descrambler result register 730. The result register is 32 bits wide in some embodiments.

At stage 640, processor 330 writes the command register to set the CMD_type field to binary value 1100. Then processor 330 reads the state 0 register. Circuit 550 (FIG. 5) reads the CMD_type field, and drives the data bus 354 with the data in the result register 730.

The byte swapping operations are performed as follows. Processor 330 sets the CRC_type field of the command register to 0111, 1000, or 1001. Then processor 330 writes the data register 380. When this happens, circuit 550 reads the data register via 32-bit bus 750, and drives the data bus 354 with the result of the swapping operation as specified in Table 1.

Appendix A illustrates Verilog hardware description language code for one implementation of circuits 520, 550 (FIG. 4). Appendix B contains Verilog code for one implementation of circuit 510.1. Appendix C contains Verilog code for one implementation of the scrambler 710. Verilog is described, for example, in D. E. Thomas et al., “The Verilog® Hardware Description Language” (1991). The invention is not limited to the embodiments of Appendices A, B and C.

The embodiments described above illustrate but do not limit the invention. In particular, the invention is not limited by any particular circuitry, the number of lines and bits in any bus or register, any particular format of the command register or other registers. The invention is not limited by any particular instructions. The invention is not limited to any particular CRC, scrambler or descrambler functions. Other embodiments may compute non-CRC check functions, known or to be invented, which may be computed on data in order to perform error detection or correction on the data. The invention is not limited by a big endian or little endian ordering. Some other ordering made by specified in the command register or some other register. Other embodiments and variations are within the scope of the invention, as defined by the appended claims.

[image]

[image]

[image]

[image]

[image]

[image]

[image]

[image]

[image]

[image]

[image]

[image]

What is claimed is:

1. A method comprising:
providing, in a register, a value identifying a function F1, wherein the function F1 is one of a plurality of functions, wherein each function in said plurality of functions is either a check function, or a scrambler function providing scrambled data, or a descrambler function providing descrambled data;
a software instruction execution circuit receiving a first software instruction; and
the software instruction execution circuit executing the first software instruction, wherein executing the first software instruction comprises:
reading, from the register, the value identifying the function F1; and
performing a computation on one or more bits of a data unit to obtain an intermediate or final result of computing the function F1 on the data unit.

2. The method of claim 1 wherein providing, in the register, the value identifying the function F1 comprises executing one or more software instructions to write, to the register, the value identifying the function F1.

3. The method of claim 1 wherein each of the functions in said plurality is a check function.

4. The method of claim 1 wherein each of the functions in said plurality is a check function or a scrambler function.

5. The method of claim 1 wherein each of the functions in said plurality is a check function or a descrambler function.

6. The method of claim 1 wherein each of the functions in said plurality is a scrambler function or a descrambler function.

7. The method of claim 1 further comprising:
writing, to the register, a value representing a function F2 which is a byte swapping function and which is not one of said plurality of functions;
a software instruction execution circuit receiving a second software instruction; and
the software instruction execution circuit executing the second software instruction, wherein executing the second software instruction comprises:
reading, from the register, the value identifying the function F2; and
computing the function F2.

8. An apparatus comprising:
a plurality of first circuits each of which each of which is to perform computations to compute a corresponding function on a data unit, wherein each of the functions corresponding to the first circuits is either a check function, or a scrambler function providing scrambled data, or a descrambler function providing descrambled data;
a register operable to store any one of a plurality of values, each value identifying a corresponding one of said functions; and
a second circuit operable, in response to a first software instruction, to activate a first circuit corresponding to the function identified by the value stored in the register.

9. The apparatus of claim 8 wherein the second circuit comprises circuitry operable to write any one of said values to the register in response to a software instruction.

10. The apparatus of claim 8 wherein the register is operable to store a value identifying a byte swapping function which is not one of said plurality of functions; and
the second circuit is operable to perform the byte swapping in response to the first software instruction when the register stores the value identifying the byte swapping function.

11. A method comprising:
a software instruction execution circuit receiving a first software instruction which is an instruction to read a value V1; and
the software instruction execution circuit executing the first software instruction, wherein executing the first software instruction comprises:
reading, from a register, a value identifying a function F1 which is one of a plurality of functions, wherein each function in said plurality is either a check function, or a scrambler function providing scrambled data, or a descrambler function providing descrambled data; and
providing, as the value V1, an intermediate or final result in a computation of the function F1.

12. The method of claim 11 further comprising, before the first software instruction is executed, writing to the register the value identifying the function F1.

13. The method of claim 12 wherein writing the value identifying the function F1 to is performed by executing one or more software instructions.

14. The method of claim 11 wherein each of said functions is a check function.

15. An apparatus comprising:
a first circuit for performing computations to compute functions on data units, wherein each of said functions is either a check function, or a scrambler function providing scrambled data, or a descrambler function providing descrambled data, the first circuit being also for storing the results of the computations;
a register operable to specify any one of said functions; and
a software instruction execution circuit for receiving a first software instruction which is an instruction to read a result of one of said computations, the software instruction execution circuit comprising circuitry for providing, in response to the first software instruction, the result of the computation associated with the function specified by the register.

16. The apparatus of claim 15 wherein the software instruction execution circuit comprises circuitry for writing the register in response to a second software instruction to cause the register to specify a function.

17. A method comprising:
a software instruction execution circuit receiving a first software instruction to perform a computation on one or more bits of a data unit, wherein the computation is to be performed to compute a function on the one or more bits of the data unit, wherein the function is either a check function, or a scrambler function providing scrambled data, or a descrambler function providing descrambled data; and
the software instruction execution circuit executing the software instruction to perform said computation;
wherein executing the software instruction comprises reading, from a register, a value representing a positive integer number N1, and performing said computation on N1 bits of the data unit.

18. The method of claim 17 further comprising, before the software instruction is executed, writing to the register the value representing the number N1.

19. The method of claim 18 wherein writing the value representing the number N1 to the register is performed by executing one or more software instructions.

20. The method of claim 17 wherein the number N1 is software programmable.

21. An apparatus comprising:
a first circuit for performing computations to compute a function on a data unit, wherein the function is either a check function, or a scrambler function providing scrambled data, or a descrambler function providing descrambled data;
a register operable to specify a number of bits on which a computation is to be performed by the first circuit; and
a software instruction execution circuit for receiving a first software instruction, and in response to the first software instruction, determining the number of bits specified by the register and activating the first circuit to perform a computation on said number of bits.

22. A method comprising:
a software instruction execution circuit receiving a first software instruction to perform a computation on a plurality of bits of a data unit, wherein the computation is to be performed to compute a function on the data unit, and wherein the function is either a check function, or a scrambler function providing scrambled data, or a descrambler function providing descrambled data; and
the software instruction execution circuit executing the software instruction to perform said computation;
wherein executing the software instruction comprises determining an ordering imposed on the plurality of bits for the purpose of executing the software instruction, and determining the ordering comprises reading a value representing the ordering from a register.

23. The method of claim 22 further comprising, before the software instruction is executed, writing a value representing the ordering to the register.

24. The method of claim 23 wherein writing the value representing the ordering to the register is performed by executing one or more software instructions.

25. An apparatus comprising:
a register specifying an ordering imposed on a plurality of bits of a data unit when a computation is performed on the plurality of bits to compute a function on the data unit, wherein the function is either a check function, or a scrambler function providing scrambled data, or a descrambler function providing descrambled data; and
a software instruction execution circuit for receiving a software instruction and performing said computation using the ordering specified by the register.

26. The apparatus of claim 25 further comprising circuitry for writing the ordering to the register in response to one or more software instructions.

27. A method for computing a cyclic redundancy check sum (CRC) on a data unit, the method comprising:
receiving, by a software instruction execution circuit, a software instruction to perform a CRC computation on one or more bits of the data unit to compute a CRC on the data unit, wherein the CRC is defined by a generator polynomial having at least three terms, and wherein the computation is to start with a predefined starting CRC value; and
executing the software instruction by the software instruction execution circuit.

28. An apparatus for computing a cyclic redundancy check sum (CRC) on a data unit, the apparatus comprising:
a first circuit for performing a CRC computation on one or more bits of the data unit to compute a CRC on the data unit, wherein the CRC is defined by a generator polynomial having at least three terms, and wherein the computation is to start with a predefined starting CRC value; and
a second circuit for receiving a software instruction and causing the first circuit to perform said computation when the software instruction is received.
